(19) United States
(12) Patent Application Publication
(10) Pub. No.: US 2010/0167430 A1
(43) Pub. Date: Jul. 1, 2010

(54) APPARATUS AND METHOD FOR TESTING A TRANSDUCER AND/OR ELECTRONIC CIRCUITRY ASSOCIATED WITH A TRANSDUCER

(76) Inventors: Colin Findlay Steele, Edinburgh (GB); John Laurence Pennock, Midlothian (GB)

Correspondence Address: DICKSTEIN SHAPIRO LLP, 1825 EYE STREET NW, Washington, DC, 20006-5403, US

(21) Appl. No.: 12/649,596

(22) Filed: Dec. 30, 2009

(30) Foreign Application Priority Data
Dec. 30, 2008 (GB) 0823675.4

(51) Int. Cl. G01R 31/26; H01L 23/50; H01L 21/66

(52) U.S. Cl. 438/15; 257/48; 324/765; 257/E23.079; 257/E21.521

(57) ABSTRACT

A method and apparatus for applying a test signal to a node of a signal path of an integrated circuit using a parasitic capacitance of the integrated circuit associated with the node. For example, a parasitic capacitance associated with a bond pad may be used to apply a test signal to a signal path. Alternatively, a parasitic capacitance associated with a shielding element may be used to apply a test signal to the signal path.

### BACKGROUND OF THE INVENTION

1. Field of the Invention

This invention relates to the field of transducers and associated electronic circuitry, and relates in particular, but not exclusively, to an apparatus and method for testing a transducer and/or electronic circuitry associated with a transducer, for example a high impedance transducer such as a micro-electrical-mechanical (MEMS) capacitive transducer.

2. Description of the Related Art

Consumer electronics devices are continually getting smaller and, with advances in technology, are gaining ever increasing performance and functionality. This is clearly evident in the technology used in consumer electronic products such as, for example, mobile phones, laptop computers, MP3 players and personal digital assistants (PDAs). Requirements of the mobile phone industry, for example, are driving components to become smaller with higher functionality and reduced cost. For example, some mobile phones now require multiple microphones for noise cancelling, or accelerometers to allow inertial navigation, while maintaining or reducing the small form factor and aiming at a similar total cost to previous generation phones.

This has encouraged the emergence of miniature transducers. For example, in respect to speech applications, initially electret microphones were used to capture speech, but more recently micro-electrical-mechanical (MEMS) transducers have been introduced. MEMS transducers may be used in a variety of applications including, but not limited to, pressure sensing, ultrasonic scanning, acceleration monitoring and signal generation. Traditionally such MEMS transducers are capacitive transducers some of which comprise one or more membranes with electrodes for read-out/drive deposited on the membranes and/or a substrate. Relative movement of these electrodes modulates the capacitance between them, which then has to be detected by associated electronic circuitry such as sensitive electronic amplifiers.

FIG. 1 illustrates a schematic diagram of a MEMS device 99 comprising a MEMS transducer 100 and an electronic circuit 102.

The MEMS transducer 100 is shown as being formed on a separate integrated circuit to the electronic circuit 102, the two being electrically connected using, for example, bond wires 112, 124. The MEMS transducer 100 comprises a MEMS capacitor C_{MEMS} having first and second plates 118, 120 that are respectively connected to first and second bond pads 114, 122.

The electronic circuit 102 comprises a charge pump 104, a diode 106, a reservoir capacitor (C_{Res}) 108, an amplifier 128, a bias circuit 131, third, fourth, and fifth bond pads 110, 126 and 130, and an optional digital-to-analogue converter (DAC) 132 with an associated sixth bond pad 134.

The following now describes the basic operation of the MEMS device.

The charge pump 104 receives a supply voltage VDD and a first reference voltage V_{REF1} and outputs an output voltage VDD* (that is greater than the supply voltage VDD). The output voltage VDD* charges up the reservoir capacitor 108, via the diode 106, to a first bias voltage Vb. The reservoir capacitor 108 supplies a relatively stable, i.e. clean, voltage Vb, via the bond pad 110, the bond wire 112 and the bond pad 114, so as to bias the first plate 118 of the MEMS capacitor C_{MEMS}.

The MEMS capacitor C_{MEMS} outputs, via the second bond pad 122, an analogue voltage signal in response to a sound pressure wave.

The amplifier 128 receives, via the bond pad 122, the bond wire 124 and the bond pad 126 the analogue voltage signal from the MEMS capacitor C_{MEMS}, and amplifies the analogue voltage signal. The amplified analogue signal, which may be a current or a voltage depending upon the type of amplifier used, is then output, for further processing, via the fifth bond pad 130. Alternatively, the electronic circuitry 102 may comprise a DAC 132, in which case, the amplified analogue signal is output, via the bond pad 134, as a digital signal. The digital signal may be output instead of, or in addition to, the amplified analogue signal. The amplifier also receives from the bias circuit 131, a second, bias voltage V_{REF2} via a bias impedance (not illustrated). The second bias voltage V_{REF2} also biases the second plate 120 of the MEMS capacitor C_{MEMS}.

As can be seen in FIG. 1, a transducer (C_{MEMS}) can be fabricated on a separate integrated circuit to its associated electronic circuitry. The separate integrated circuits (100, 102) can either be packaged separately, or mounted on a common substrate within the same package. When the transducer and associated electronic circuitry are formed on separate integrated circuits, interconnecting elements such as bond wires (as shown in FIG. 1), or studs, bumps etc. are used to electrically interconnect the separate integrated circuits. It should be noted that a transducer and its associated electronic circuitry can also be fabricated on the same integrated circuit, i.e. a fully integrated solution. The present invention is equally applicable and or adaptable to such fully integrated solutions.

As with conventional silicon technology, MEMS technology allows much of the manufacturing process to be performed on many devices at once, on a whole wafer containing thousands of devices, or even a batch of dozens of wafers. This fundamentally reduces production cost. Wafer-scale packaging techniques may also be used with similar benefits.

However the production process contains many steps, not only the silicon-level processing steps, but also later steps, for example placing the transducer on a common underlying substrate with the amplifier and biasing electronics, adding bond wires between the transducer and the electronics and from the electronics to terminals on the substrate, covering the assembly with protective material, and adding a case to cover the assembly. At each stage, processing errors may occur, or random defects may degrade the device, so it is desirable to be able to test the functionality of the sub-components and their interconnections as soon as possible in the manufacturing process to avoid wasting the cost of materials, and processing devices that will be rejected at final test.

It is not straightforward to apply conventional wafer-test techniques to capacitive transducers and their associated electronic circuitry. For example in the case of a microphone application, it is impractical to apply a controlled acoustic stimulus to each MEMS die on a wafer. Also, because of the very low capacitance of the sensor (possibly less than 1 pf), and hence the small input capacitance of the amplifier electronics, there may be little or no electrostatic discharge (ESD) protection on the amplifier input, so these inputs are liable to damage if probed directly during testing. Also the amplifier performance may be altered by the parasitic capacitance of the probes being applied to its input. Therefore, it is desirable to be able to test the functionality, electrical continuity and/or performance of the device with neither an acoustic stimulus nor direct electrical contact to sensitive circuit nodes.

Furthermore, the need for low cost and high volume means that the test time should be as short as possible, so preferably tests for gross failure modes should be performed and samples failing these functional tests should be removed from test before any time-consuming precision tests are carried out. Once a production line is characterised and under Statistical Process Control, a largely functional test may be adequate to obtain a low defect rate. However, even on a mature process there is the need for occasional auditing and re-characterisation to allow yield optimisation or to help diagnose the causes of any reduction in yield. It is useful to be able to access different nodes in any circuitry to provide clues to any yield sensitivity, for example to localise a problem to a particular part of the circuitry.

However, one problem in fully testing finished devices is that because of size constraints on the overall package size, there may only be a very small number of external connections to the transducer/circuit assembly, possibly as few as three (ground, supply, and output). This makes it difficult to access internal nodes in a circuit, so as to apply electrical signals to these nodes, for such test and diagnostic purposes.

The present invention seeks to provide an apparatus and method for applying a test signal to a node of a signal path, for example a signal path associated with a transducer and/or electronic circuitry associated with a transducer such as a MEMS capacitive transducer, that allows test stimuli to be applied without a physical stimulus (e.g. pressure stimulus) or direct external electrical connection to critical nodes (e.g. probing sensitive nodes), while not impacting performance nor requiring complex additional circuitry.

### SUMMARY OF THE INVENTION

According to a first aspect of the present invention there is provided an integrated circuit having a signal path. The integrated circuit comprises means for coupling a test signal to a node of the signal path via a parasitic capacitance of the integrated circuit associated with the node.

According to another aspect of the present invention, there is provided a method of applying a test signal to a node of a signal path of an integrated circuit. The method comprises the steps of coupling a test signal to the node via a parasitic capacitance of the integrated circuit associated with the node.

The invention has the advantage of enabling a test signal to be coupled to a signal path via a parasitic capacitance of the integrated circuit already associated with a signal node on the signal path. This has the advantage of enabling a test signal to be applied without adding any further parasitic capacitances into the system, which means that the test circuitry does not have any degrading effect during a normal mode of operation. A parasitic capacitance of the integrated circuit, i.e. an inherent parasitic capacitance is used. Furthermore, the invention avoids the need to directly probe sensitive parts of the signal path, for example the input of an amplifier during the testing procedure.

According to another aspect of the present invention, there is provided an integrated circuit for processing a signal associated with a capacitive transducer, the integrated circuit comprising a circuit as claimed in the appended claims.

According to a further aspect of the present invention, there is provided a method of testing an assembly comprising a first integrated circuit comprising a capacitive transducer and a second integrated circuit comprising associated electronic circuitry. The method comprises the steps of: mounting the first integrated circuit and the second integrated circuit on a common substrate; and testing the first integrated circuit and/or the second integrated circuit using the method as defined in the appended claims, prior to the step of electrically connecting the first integrated circuit and the second integrated circuit.

According to a further aspect of the invention there is provided a method of testing an assembly comprising a first integrated circuit comprising a capacitive transducer and a second integrated circuit comprising associated electronic circuitry. The method comprises the steps of: mounting the first integrated circuit and the second integrated circuit on a common substrate; electrically connecting the first integrated circuit and the second integrated circuit; and testing the first integrated circuit and/or the second integrated circuit using the method as defined in the appended claims.

In one embodiment there is provided there is provided a circuit for applying a test signal to a node of a signal path. The circuit comprises means for coupling a test signal to the node of the signal path via a parasitic capacitance associated with the node.

### BRIEF DESCRIPTION OF THE DRAWINGS

For a better understanding of the invention, and to show more clearly how it may be carried into effect, reference will now be made, by way of example only, to the accompanying drawings in which:

FIG. 1 is a schematic diagram of a MEMS device comprising a MEMS transducer interfaced with electronic circuitry;

FIG. 2 illustrates a parasitic capacitance associated with a bond pad;

FIG. 3 illustrates some of the parasitic capacitances associated with the circuit of FIG. 1;

FIG. 4 is a schematic diagram illustrating as example of how an electrical connection can be made with the parasitic capacitance shown in FIG. 2;

FIG. 5a is a schematic diagram illustrating how a parasitic capacitance can be used to apply a test signal according to one embodiment of the present invention;

FIG. 5b is a schematic diagram illustrating how one or more other parasitic capacitances can be used to apply a test signal according to other embodiments of the invention;

FIGS. 6a and 6b illustrate a transistor that can be used in an electronic circuit;

FIGS. 7a to 7d illustrate examples of shielding elements that can be used to protect a signal path or terminal of the transistor shown in FIGS. 6a and 6b;

FIG. 8 is a schematic diagram illustrating how a parasitic capacitance associated with a shielding element can be used to apply a test signal according to one embodiment of the present invention;

FIG. 9 is a flow chart showing the steps performed in a conventional testing procedure; and

FIG. 10 is a flow chart showing the steps performed in a method of testing according to another aspect of the present invention.

### DETAILED DESCRIPTION OF THE PREFERRED EMBODIMENTS

The description of the embodiments below will be made in relation to a MEMS device in the form of an analogue/digital microphone. However, it will be appreciated that some or all aspects of the present invention may also be applicable to any other type of high input impedance, or small output signal, transducers such as capacitive MEMS devices and/or capacitive transducers, including non-MEMS type capacitive transducers.

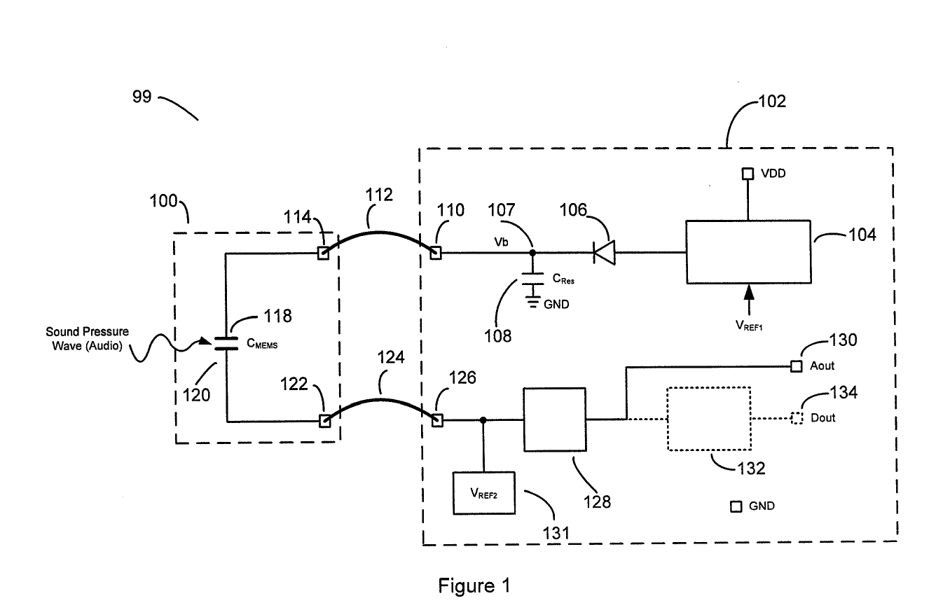

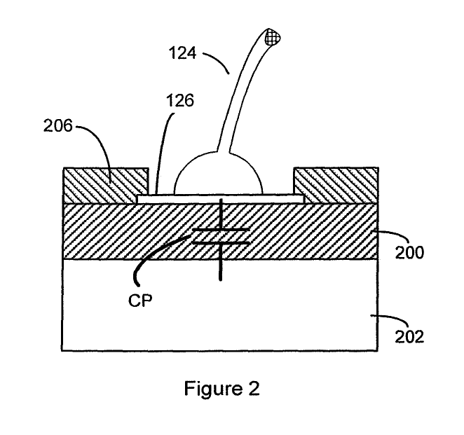

FIG. 2 shows a bond pad, for example the bond pad 126 of FIG. 1, in further detail. As will be familiar to a person skilled in the art, generally a bond pad is an area of metal, for example (although not necessarily) square in shape, that is on the one hand electrically connected to a component or connection within an integrated circuit to which the bond pad is attached, and on the other hand enables electrical connection to an external integrated circuit, component or connection (for example via a bond wire 124, as illustrated, that is connected to an exposed surface of the bond pad 126, or a “flip-chip” arrangement, not illustrated, whereby a metal ball or stud is formed on the bond pad 126 for electrical connection with a similar bond pad mounted on a separate integrated circuit).

A bond pad 126 is typically formed on an oxide or dielectric layer 200, which is in turn formed on a substrate 202, for example a silicon wafer. A passivation layer 206 may be formed on the oxide or dielectric layer 200 and etched away to expose the bond pad 126. The bond pad has an associated parasitic capacitance (illustrated by the capacitor CP). This parasitic capacitance CP exists between the bond pad 126 and the substrate 202 such that it is present in the oxide or dielectric layer 200. A bond wire 124 (for example, gold, aluminium or copper) is shown connected to the bond pad 126 and is used for connecting the bond pad to another component, for example another bond pad (not shown) which, like all bond pads, will also have a respective parasitic capacitance.

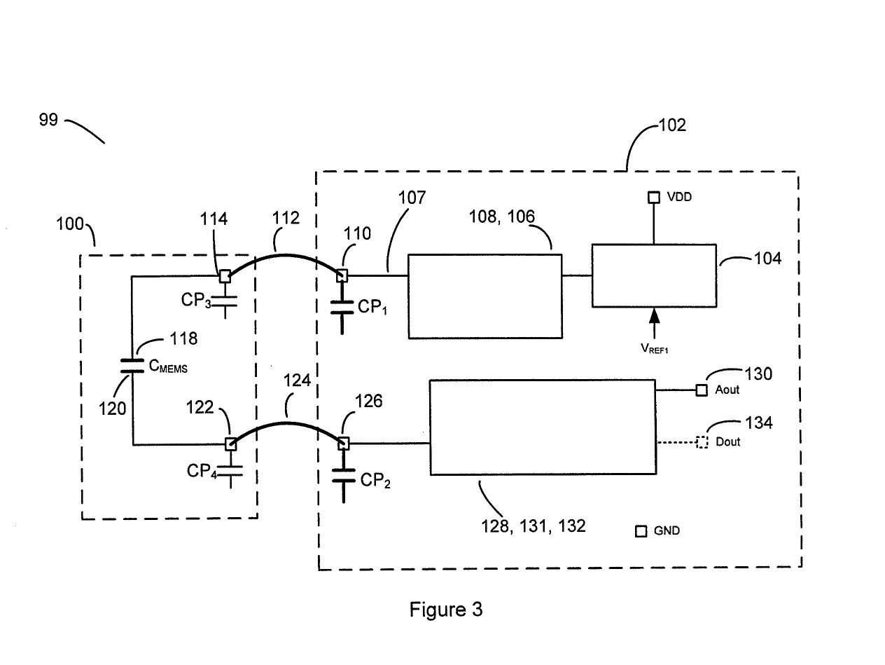

FIG. 3 illustrates the parasitic capacitances of the bond pads, as shown in FIG. 2, as they apply to FIG. 1. FIG. 3 is similar to the arrangement of FIG. 1, with common features having common reference numbers. It is noted that certain features have been simplified for clarity in order to highlight the invention. As can be seen, each bond pad 110, 126, 114, 122 has an associated parasitic capacitance CP₁ to CP₄. These are parasitic capacitances of the integrated circuit, i.e. inherent parasitic capacitances.

According to a first aspect of the invention a parasitic capacitance, for example an otherwise unwanted parasitic capacitance CP associated with a bond pad, for example bond pad 110 or band pad 126 on the electronic circuitry 102, may be used to route a signal, such as a test signal. According to one aspect of the invention, test circuitry is provided and is operatively connected to a signal path via a parasitic capacitance, for example a parasitic capacitance associated with a bond pad connected to the signal path. A test signal may be applied at one or more locations where a parasitic capacitance exists, for example one or more locations where a bond pad exists.

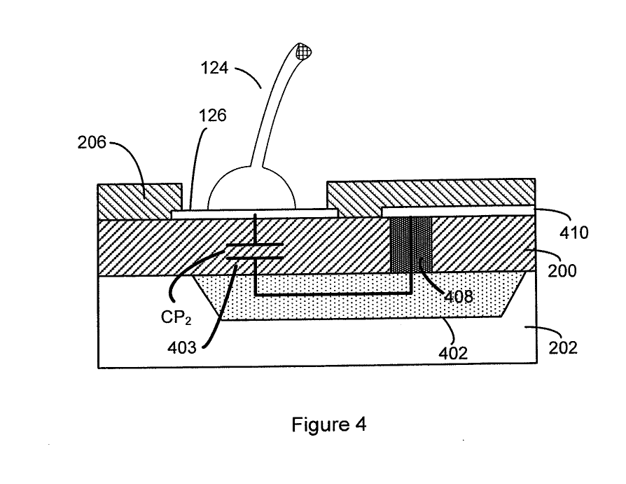

FIG. 4 shows an example of how a bond pad, for example bond pad 126, can be adapted according to one embodiment of the present invention, which takes advantage of a parasitic capacitance CP generally associated with bond pads (i.e. parasitic capacitance CP₂ associated with bond pad 126), such that this embodiment can be used to aid the testing of the MEMS transducer 100 and/or its associated electronic circuitry 102.

With reference to FIG. 4, a conductive region, for example an n-well 402 (assuming a p-type substrate 202), deposited under or near the bond pad is used to access, the otherwise inaccessible, bottom plate 403 of the parasitic capacitance CP₂, and hence enable a test signal (not shown) to be connected via this parasitic capacitance CP₂ to the electronic circuitry 102 associated with the capacitive transducer 100, for example to a node of the signal path of the electronic circuitry. In a similar manner, a test signal can be applied using one or more of the other bond pads 110, 114, 122 for enabling the capacitive transducer 100 and/or its associated electronic circuitry 102 to be tested.

The conductive region 402 can either be a conductive region that is specially formed beneath the parasitic capacitance for this purpose, or a conductive region that already exists in the region of the parasitic capacitance.

The bond pad is formed on an oxide or dielectric layer 200, which is in turn formed on a substrate 202, for example a silicon wafer. The, previously deposited, n-well 402 is formed within the (p-type) substrate 202 under where a bond pad is required, such that the upper surface of the n-well 402 and the upper surface of the substrate 202 form a planar surface on which the oxide or dielectric layer 200 is formed. In a CMOS process such an n-well layer will already be present elsewhere on the integrated circuit, to aid the fabrication of PMOS transistors, and therefore the addition of the n-well 402 under the site of a required bond pad only requires modification of the mask layout, and not any additional manufacturing steps. The invention is intended also to embrace any other method or process for forming a conductive layer such as the n-well 402, as will be familiar to a person skilled in the art, for example using a base or emitter layer in a bipolar or BiCMOS process. Furthermore, the invention applies to the use of a p-well when the substrate in formed from n-type material. The invention therefore embraces any method or process for enabling an electrical connection to be made with the bottom plate of the parasitic capacitance.

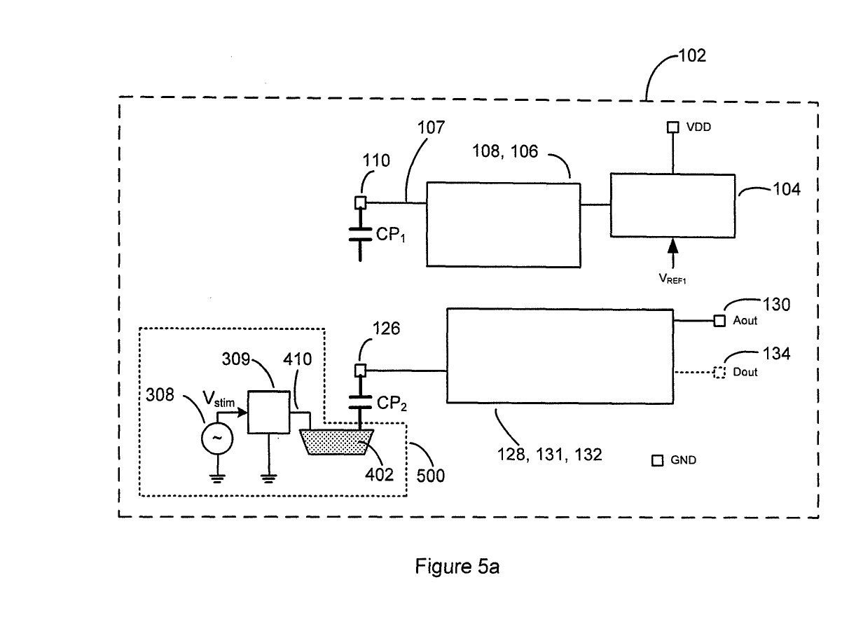

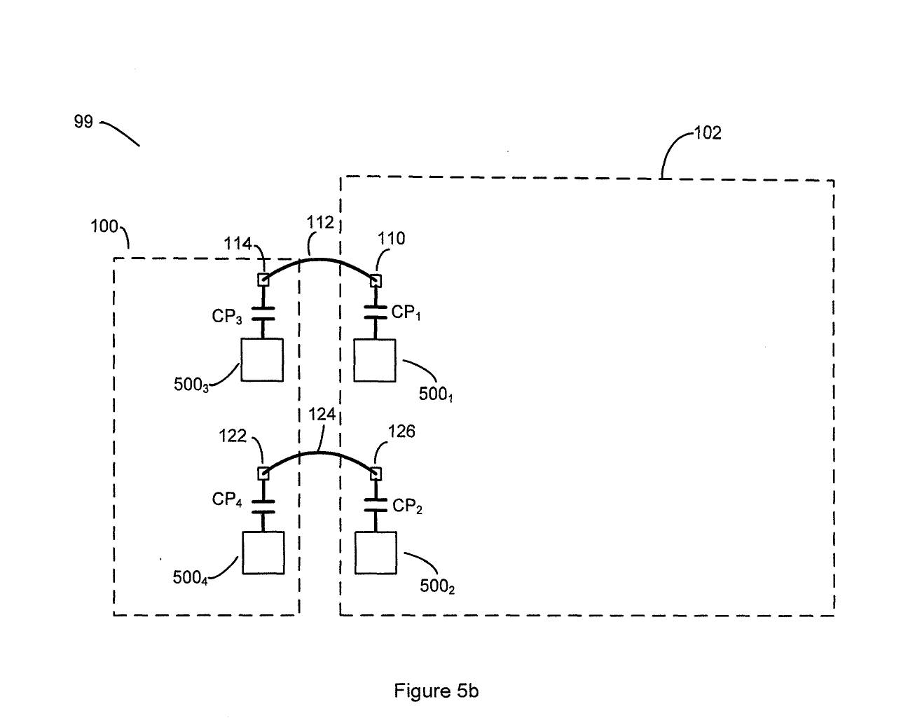

FIG. 5a will be used to illustrate how the parasitic capacitance CP₂ associated with the bond pad 126 can be used to couple a test signal to a node of the signal path of the electronic circuitry associated with the capacitive transducer. It will be appreciated, however, that the other bond pads may also be used to apply a test signal to other nodes on the signal path, for testing the capacitive transducer and/or the electronic circuitry associated with the capacitive transducer.

Referring now to FIG. 5a, the provision of the n-well 402 enables a test signal Vₛₜᵢₘ to be connected to a signal path via the parasitic capacitance CP₂. This may involve passing the test signal Vₛₜᵢₘ through a conductor 410, an interconnect 408 (shown in FIG. 4), the n-well 402 and the parasitic capacitance CP₂. It will be appreciated that other methods may be used to connect the test signal to the parasitic capacitance CP₂.

During a test mode, the bottom plate of the parasitic capacitance CP₂ is connected to receive the test signal Vₛₜᵢₘ, for example via a switch 309, from a signal source 308. As such, the switch 309 is adapted to selectively couple the test signal to the node of the signal path, via the parasitic capacitance, during a test mode of operation. During normal operation the bottom plate of the parasitic capacitor CP₂ may be connected to a “clean” reference voltage such as a start-connected ground voltage. It is noted, however, that the bottom plate of the parasitic capacitor CP₂ may be connected to some other form of voltage reference, if desired, during normal operation. For example, the bottom plate of the parasitic capacitance may be connected to receive a bootstrap signal to compensate for the effect of the parasitic capacitance, as described in greater detail in co-pending application GB0823665.5 (Ref P1196 GB00) by the present applicant.

It is noted that the signal source 308 and/or switch 309 may either be provided on-chip or off-chip, or partly on-chip and partly off-chip. If the signal source 308 is provided off-chip, the conductor 410 can be coupled to a dedicated bond pad for receiving the test signal, or an existing bond pad that is temporarily assigned i.e. switched, for this purpose.

In the example shown in FIG. 5a, the parasitic capacitance CP₂ of the second bond pad 126 may be used, using the embodiment of FIG. 4, to allow testing, by the test circuitry 500, of one or more first parts 128,131,132 of the electronic circuit 102.

Referring to FIG. 5b (in which certain features of FIG. 5a have been omitted for clarity), the test circuitry 500₁ to 500₄, whether in whole or in part, may be configured to provide a test signal to any one or more of the bond pads 110, 126, 114, 122, thereby enabling the capacitive transducer and/or the electronic circuitry associated with the capacitive transducer to be tested, for example by applying a test signal to different nodes or portions of the signal path. It is noted that a test signal Vₛₜᵢₘ can be applied to the signal path using any other parasitic capacitance that is known to exist on the MEMS transducer 100 and/or electronic circuit 102, i.e. in addition or as an alternative to the parasitic capacitances CP₁ to CP₄ associated with the bond pads 110, 126, 114, 122.

For example, according to another aspect of the present invention, the test signal may be routed via a parasitic capacitance generally associated with shielding elements of shielded signal paths. Such a shielding parasitic capacitance CPₛ can be used to aid the testing of the MEMS transducer 100 and/or its associated electronic circuitry 102, as described below.

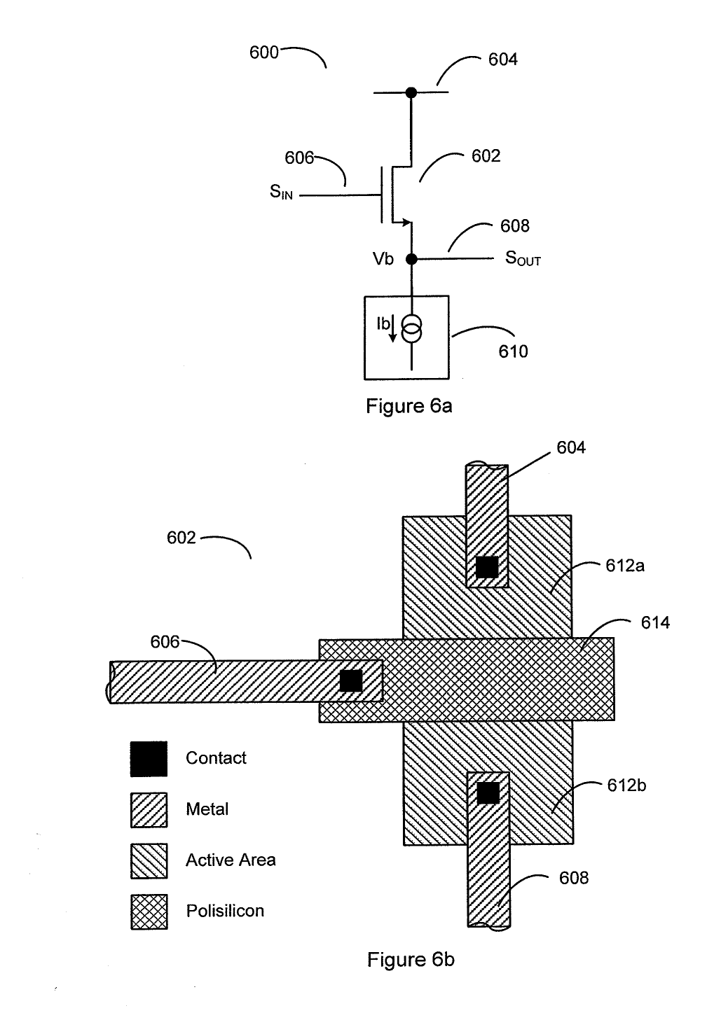

FIG. 6a illustrates an embodiment of an input stage 600 of an amplifier used for amplifying a signal from a MEMS transducer (not illustrated).

The NMOS transistor 602 is connected to receive: a supply voltage 604 on its drain terminal; the signal S_{IN} to be amplified on its gate terminal 606; and an output signal S_{OUT} (i.e. the buffered input signal S_{IN}) of its source terminal 608. The source terminal 608 is also connected to receive a bias voltage Vb at its source terminal 608 from a current (Ib) bias circuit 610.

In the embodiment illustrated the input transistor 602 to the amplifier is connected as a source follower. Other embodiments of input stages 600 and/or transistors 602 will be appreciated by those skilled in the art. It will also be appreciated that the circuit arrangement of FIG. 6a will, in practice, be surrounded by other circuitry including voltage supply lines, signal paths and/or substrate depositions. Such features have been omitted for clarity.

FIG. 6b illustrates a plan view of a typical integrated circuit layout of the transistor 602 of FIG. 6a.

Above an active area region 612a, 612b a polysilicon gate region 614 is deposited. Between the active area drain region 612a, the active area source region 612b and the gate region 614 are respective contacts to the drain metal interconnect 604, the source metal interconnect 608 and the gate metal interconnect 606.

According to this aspect of the present invention, a terminal of transistor 602, for example the gate terminal 606 of transistor 602, is preferably shielded by one or more shielding planes or tracks that are connected to a stable, clean, reference voltage such as ground, i.e. 0V, for example. Therefore, during normal operation, the shielded gate terminal 606 will not pick up any stray crosstalk signals from surrounding interconnects, substrate depositions and/or circuitry that would otherwise be superimposed upon the low voltage output signal from the transducer that appears on the sensitive signal 606 path between the bottom plate of the transducer and the input to the amplifier. According to this aspect of the invention, a parasitic capacitance associated with a shielding element is used to apply or route a test signal onto the signal path. Thus, in this embodiment, a shielding element acts as a conductive region associated with a parasitic capacitance of a node on the signal path.

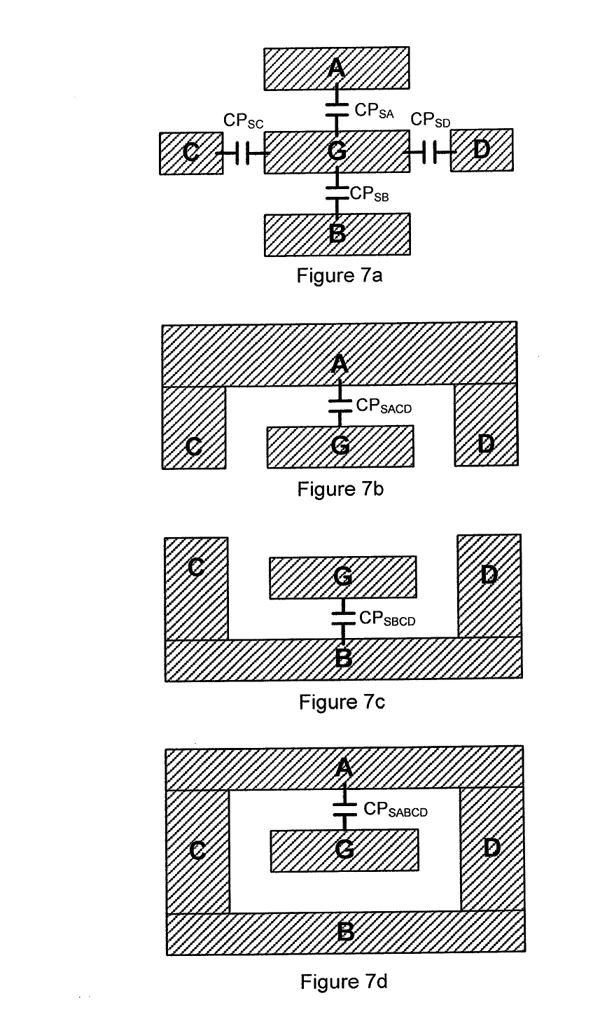

FIGS. 7a to 7d illustrate some example shielding arrangements as they may be applied to FIGS. 6a and 6b. It will be appreciated that these are examples only, and that any configuration of shielding elements may be used.

FIG. 7a shows a gate terminal G (for example corresponding to the gate terminal 606 in FIG. 6b) having shielding elements A, B, C and D. A parasitic capacitance CP_{SA}, CP_{SB}, CP_{SC}, CPs_{SD} is associated with each shielding element A, B, C and D, respectively. A test signal may be applied to the signal path on the gate terminal G using any one or more of the parasitic capacitances CP_{SA}, CP_{SB}, CP_{SC}, CP_{SD}. For example, a test signal may be selectively connected to a shielding element A, B, C or D during a test mode of operation, with the shielding element A, B, C or D being connected to its normal connection, for example a ground connection, during a normal mode of operation.

FIG. 7b shows an alternative arrangement of shielding elements arranged around the gate terminal G. The arrangement shown in FIG. 7b comprises shielding elements A, C and D, which provide an effective parasitic capacitance of CP_{SACD}. As with FIG. 7a, a test signal may be applied to the signal path on the gate terminal G via the parasitic capacitance CP_{SACD}. For example, a test signal may be selectively connected to the shielding element A, C, D during a test mode of operation, with the shielding element A, C, D being connected to its normal connection, for example a ground connection, during a normal mode of operation.

FIG. 7c shows an alternative arrangement of shielding elements arranged around the gate terminal G. The arrangement shown in FIG. 7c comprises shielding elements B, C and D, which provide an effective parasitic capacitance of CP_{SBCD}. As with FIGS. 7a and 7b, a test signal may be applied to the signal path on the gate terminal G via the parasitic capacitance CP_{SBCD}. For example, a test signal may be selectively connected to the shielding element B, C, D during a test mode of operation, with the shielding element B, C, D being connected to its normal connection, for example a ground connection, during a normal mode of operation.

FIG. 7d shows an alternative arrangement of shielding elements arranged around the gate terminal G. The arrangement shown in FIG. 7d comprises shielding elements A, B, C and D, which are interconnected and provide an effective parasitic capacitance of CP_{SABCD}. As with FIGS. 7a, 7b and 7c, a test signal may be applied to the signal path on the gate terminal G via the parasitic capacitance CP_{SABCD}. For example, a test signal may be selectively connected to the shielding element A, B, C, D during a test mode of operation, with the shielding element A, B, C, D being connected to its normal connection, for example a ground connection, during a normal mode of operation.

It is noted that the parasitic capacitance per unit length of shielding element, for example for 0.35 micron process shown in FIGS. 7a to 7d, is approximately 200 fF/mm. Therefore, a shielding element of about 250-1000 micron results in a parasitic capacitance of about 50 fF.

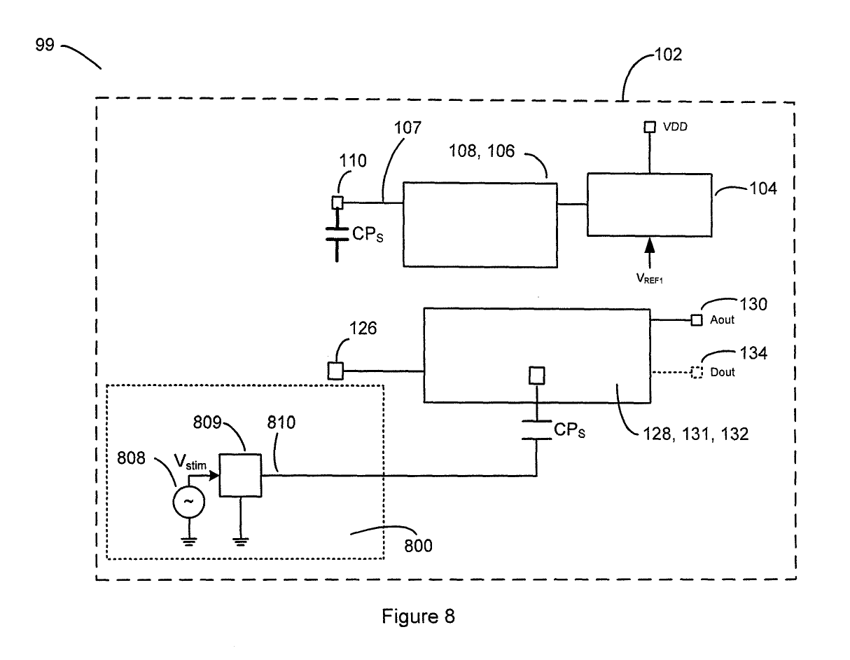

FIG. 8 illustrates how a parasitic capacitance CP_{S} associated with a shielding element can be used with test circuitry 800 to apply a test signal Vₛₜᵢₘ to a node of a signal path in the electronic circuitry. This may involve passing the test signal Vₛₜᵢₘ, via a switch 809 and a conductor 810 coupled to the parasitic capacitance CP_{S}. It will be appreciated that other methods may be used to connect the test signal to the parasitic capacitance CP_{S}.

During a test mode, the parasitic capacitance CP_{S} is connected to receive the test signal Vₛₜᵢₘ, for example via a switch 809, from a signal source 808. During normal operation the parasitic capacitor CP_{S} may be connected to a “clean” reference voltage for shielding the signal path, for example a ground voltage.

It is noted that each of the signal source 808 and/or switch 809 may either be provided on-chip or off-chip, or partly on-chip and partly off-chip. If the signal source 808 is provided off-chip, the conductor 810 can be coupled to a dedicated bond pad for receiving the test signal, or an existing bond pad that is temporarily assigned i.e. switched, for this purpose.

Although FIG. 8 shows the test signal being applied to a shielding element associated with the electronic circuitry 128, 131, 132, it is noted that the test signal may be applied via any shielding element, including shielding elements associated with the signal path “upstream” of the MEMS transducer, thereby enabling the tests described in the embodiments above to be carried out.

The present invention is not limited to any particular test signal. For example, the test signal Vₛₜᵢₘ may be a constant AC signal having a particular frequency and/or amplitude. In an alternative embodiment the test signal Vₛₜᵢₘ may comprise a more complex signal, for example a signal that is swept through a particular range of frequencies and/or amplitudes. The switch 309, 809 may be configured to connect the parasitic capacitance CP to a voltage reference, for example ground, when not being used in a test mode of operation. Further details of other forms of test signal that can be routed via the parasitic capacitances may be found in co-pending application P1195 GB00 by the present applicant.

It will therefore be appreciated that the various embodiments of the invention enable a test signal to be coupled to a signal path via a parasitic capacitance associated with a signal node on the signal path. This has the advantage of enabling a test signal Vₛₜᵢₘ, to be applied without adding any further parasitic capacitances into the MEMS transducer 100 and/or electronic circuit 102, which means that the test circuitry 500, 800, or any part thereof, does not have any degrading effect during the normal mode of operation of the MEMS transducer 100 and electronic circuit 102. As a consequence, the test circuitry 500, 800, or any part thereof, does not affect the gain of the signal from the MEMS transducer 100 during normal operation. Furthermore, the invention avoids the need to probe the sensitive input of the amplifier 128 during the testing procedure. In addition, when the signal source 308, 808 is provided on-chip, it also avoids the need for any additional I/O pads to be provided.

It will be appreciated that the various embodiments described above enable the MEMS device 100 and electronic circuit 102 to be tested in a number of different ways.

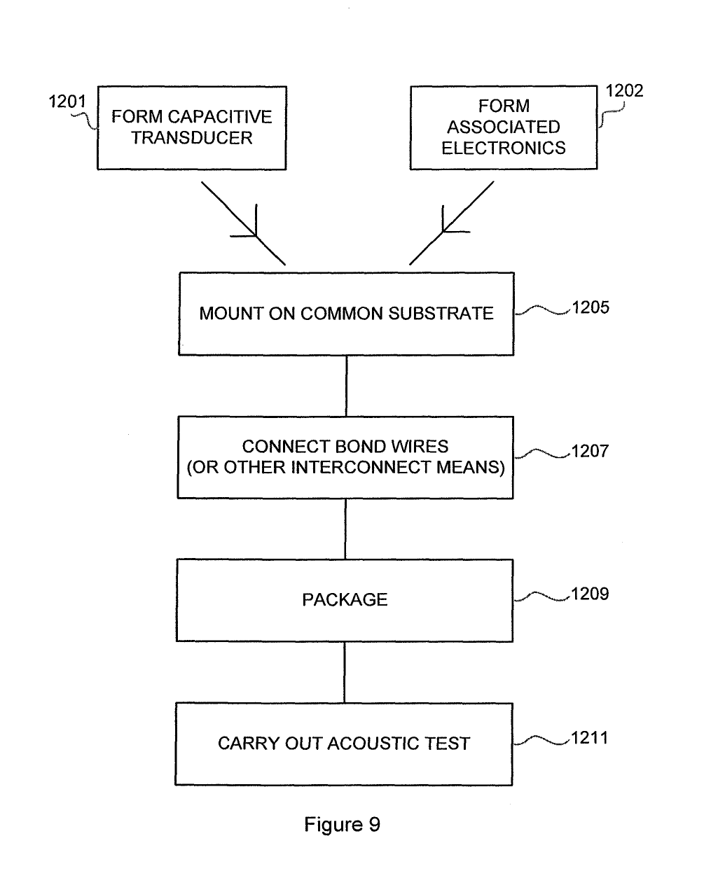

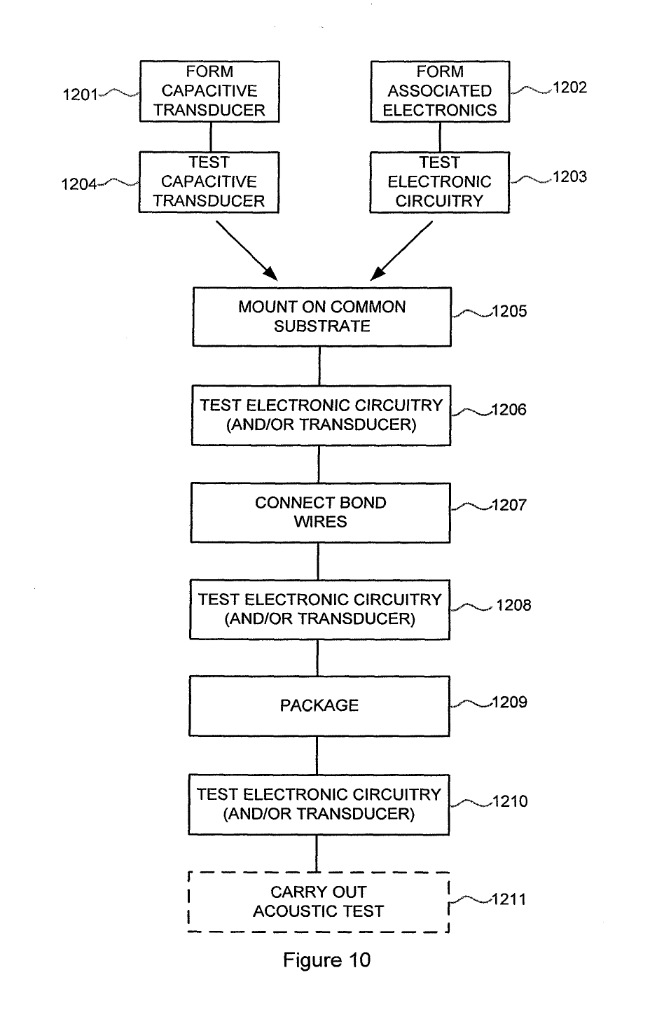

In the embodiments of FIGS. 5a, 5b, 6a, 6b, 7a, 7b, 7c, 7d and 8 the parasitic capacitance CP associated with a bond pad or shielding element, for example, enables a simulated test signal to be passed through the MEMS microphone to the electronic circuit 102. This enables the signal path to be tested. For example, by monitoring the presence or absence of an expected output signal of the electronic circuitry 102 the test mode enables the continuity of the path to the MEMS microphone (i.e. via the bond pads 110, 114 and bond wire 112), and from the MEMS microphone to the electronic circuitry (i.e. via bond pads 122, 126 and bond wire 124) to be tested. The test signal also enables some parameters of the MEMS microphone such as resonance frequency to be tested, and also parameters of the LNA 128, such as gain or bandwidth or circuit noise, by monitoring parameters of an output signal of the electronic circuitry 102. These tests can be performed during various stages of the manufacturing process, as will be described below in relation to FIGS. 9 and 10.

Also, the parasitic capacitance CP associated with the bond pads or shielding elements, for example, enable a test signal to be applied to the LNA 128 thus allowing the latter part of the electronic circuit 102 to be tested. This part of the electronic circuit 102 can be tested either before the MEMS device 100 is connected to the electronic circuit 102, or after the MEMS device 100 is connected, as described below in greater detail with reference to FIGS. 9 and 10. In the former example, this enables the electronic circuitry to be tested prior to placing the bond wires, thus saving cost if a faulty device is detected.

Further details will now be given concerning how the testing procedures can be carried out in relation to the fabrication or manufacture of a MEMS device.

FIG. 9 shows the traditional steps involved in the manufacture of a MEMS device whereby the MEMS transducer is formed on a first integrated circuit in step 1201, while the associated electronic circuit is formed on a separate integrated circuit in step 1202. The individual integrated circuits for the MEMS transducer and associated electronic circuit may be formed in a number of different ways, including the use of separate wafers whereby each wafer contains a large number of each integrated circuit, which are then singulated or diced to provide the individual integrated circuit dies required for steps 1201 and 1202.

In step 1205 the individual MEMS transducer IC and individual electronic circuit IC are mounted on a common substrate. Bond wires (or any other mechanism for connecting the two circuits) are then used to electrically connect the MEMS transducer with the associated electronic circuit, step 1207. This step may also involve adding bond wires between the respective circuits and the bond pads or connections that interface the final packaged device with the outside world.

Once the circuit has been electrically connected in step 1207 the device is then packaged in step 1209. This may include one or more of the following processes: addition of a protective layer to protect the device from environmental parameters; addition of a sealed package; addition of a lid having an acoustic hole. Other packaging processes may also be used.

The fully assembled MEMS device can then be tested in step 1211 by applying an acoustic stimulus for driving the moveable membrane of the capacitive transducer, and observing the output signal to determine if the device is faulty or working.

It will be appreciated that this form of testing is not suitable for high volume manufacture, since the step of providing an accurate acoustic stimulus is difficult to perform. Furthermore, performing the test after the final stage of assembly is not cost effective, since a faulty transducer or electronic circuit may have been fully assembled unnecessarily. In addition, the use of traditional probing techniques to probe certain nodes prior to the device being packaged can damage sensitive nodes on the electronic circuitry.

According to a further aspect of the present invention, FIG. 10 describes the steps involved in testing a MEMS device during a manufacturing process.

In step 1201a MEMS transducer is formed on a first integrated circuit, and in step 1202 the associated electronic circuit is formed on a separate integrated circuit. As mentioned above, the individual integrated circuits for the MEMS transducer and associated electronic circuit may be formed in a number of different ways, including the use of separate wafers whereby each wafer contains a large number of each integrated circuit, which are then singulated or diced to provide the individual integrated circuit dies required for steps 1201 and 1202.

According to the invention, in step 1203 the electronic circuit may be tested using any of the methods described above in relation to the embodiments of FIGS. 5a, 5b, 6a, 6b, 7a, 7b, 7c, 7d and 8. For example, any part of the circuitry 128, 131, 132 and/or their interconnections, including their interconnection to bond pad 126, can be tested by applying a test signal via a parasitic capacitance, for example a parasitic capacitance associated with a bond pad or a shielding element. In addition, or alternatively, the functioning of the reservoir capacitor, and its interconnection to the bond pad 110 and charge pump 104 can be tested using a parasitic capacitance associated with a bond pad or shielding element, for example. Also, the dynamic recovery of the charge pump 104 may be tested via a parasitic capacitance, for example via CR₁ or some other parasitic capacitance or shielding element provided in that part of the electronic circuitry. As a consequence, any defective parts can be discarded prior to being used in the assembly process.

The MEMS transducer may also be tested in step 1204, for example using parasitic capacitances CP₃ and/or CP₄, or a parasitic capacitance associated with a shielding element in that part of the circuit.

In step 1205 the individual MEMS transducer IC and individual electronic circuit IC are mounted on a common substrate.

However, prior to adding bond wires in step 1207 (or any other mechanism for connecting the two circuits), the electronic circuit can first be tested in step 1206 using any of the methods described in FIGS. 5a, 5b, 6a, 6b, 7a, 7b, 7c, 7d and 8. Also, if desired, the MEMS transducer can be tested at this point. The test signals may be applied via any one or more or the parasitic capacitances associated with the signal path, including any one or more of the bond pads 110, 126, 114, 122, or any shielding element associated with the signal path.

This enables the individual devices to be tested after being mounted on the common substrate, to determine whether or not this processing step has damaged either of the integrated circuits.

In step 1207 bond wires (or any other mechanism for connecting the two circuits) are used to electrically connect the MEMS transducer with the associated electronic circuit. This step may also involve adding bond wires between the respective circuits and the bond pads or connections that interface the final packaged device with the outside world.

Once the MEMS transducer and electronic circuitry have been electrically connected, the MEMS transducer and/or associated circuitry can then be tested in step 1208 using any of the methods described above in relation to FIGS. 5a, 5b, 6a, 6b, 7a, 7b, 7c, 7d and 8. For example, a test signal may be passed via parasitic capacitance CP₁, or a shielding element in that part of the circuit, through the MEMS microphone to the electronic circuit 102. This enables the signal path to be tested. For example, by monitoring the output signal the test mode enables the continuity of the path to the MEMS microphone (i.e. via the bond pads 110, 114 and bond wire 112), and from the MEMS microphone to the electronic circuitry (i.e. via bond pads 122, 126 and bond wire 124) to be tested. The test signal also enables the MEMS microphone itself to be tested, and the performance of the LNA 128 circuitry. As another example, a test signal may be passed via parasitic capacitance CP₂, or a parasitic capacitance associated with a shielding element in that part of the circuit, to test only the electronic circuitry in the lower portion of the electronic circuit 102, i.e. the circuitry after the capacitive transducer.

From the above it will be appreciated that the MEMS transducer, interconnection nodes and electronic circuitry can be tested prior to the assembled device being packaged, without requiring additional test pins, without needing to probe sensitive nodes, and without requiring an acoustic stimulus.

Once the assembled device has been tested as noted above, the device can then be packaged in step 1209. As mentioned above, this may include one or more of the following processes: addition of a protective layer to protect the device from environmental parameters; addition of a sealed package; addition of a lid having an acoustic hole. Other packaging processes may also be used.

The fully assembled MEMS device can then be tested in step 1210 using any of the techniques described above. For example, a test signal may be passed via parasitic capacitance CP₁, or a parasitic capacitance associated with a shielding element in that part of the circuit, through the MEMS microphone to the electronic circuit 102. This enables the signal path to be tested. For example, by monitoring the output signal the test mode enables the continuity of the path to the MEMS microphone (i.e. via the bond pads 110, 114 and bond wire 112), and from the MEMS microphone to the electronic circuitry (i.e. via bond pads 122, 126 and bond wire 124) to be tested. The test signal also enables the MEMS microphone itself to be tested, and the performance of the LNA 128 circuitry. As another example, a test signal may be passed via parasitic capacitance CP₂, or a parasitic capacitance associated with a shielding element in that part of the circuit, to test only the electronic circuitry in the lower portion of the electronic circuit 102, i.e. the circuitry after the capacitive transducer.

It will be appreciated that the MEMS transducer, interconnection nodes and electronic circuitry can be tested after being packaged (i.e. when probing is no longer possible), without requiring an acoustic stimulus. The testing also avoids the need for additional test pins.

Finally, if desired, in step 1211 a further test can be carried out, for example on a random basis rather than on every device, whereby an acoustic stimulus is applied for driving the moveable membrane of the capacitive transducer, and observing the output signal to determine if the device is faulty or working.

FIG. 10 describes a manufacturing process whereby the MEMS microphone 100 and the electronic circuit 102 are formed on separate integrated circuits, with bond pads and bond wires connecting the separate integrated circuits, which are then packaged on a common substrate.

However, it will be appreciated that the MEMS microphone 100 and electronic circuit 102 can also be formed on the same integrated circuit within the packaged device, i.e rather than on two separate integrated circuits. It will be appreciated that in this case the bond pads and bond wires can be avoided. However, the testing method and circuit described in relation to FIGS. 5a, 5b, 6a, 6b, 7a, 7b, 7c, 7d and 8 may still be used even when the bond pads and bond wires are not present. In other words, the injection of a test signal via a parasitic capacitance may also be carried out in a fully integrated solution when the MEMS device and electronic circuit are all provided on the same integrated circuit.

As mentioned above, although the various embodiments describe a MEMS capacitive microphone, the invention is also applicable to any form of high impedance or capacitive transducer, including non-MEMS devices, and including transducers other than microphones, for example accelerometers or ultrasonic transmitters/receivers.

It is noted that the embodiments described above may be used in a range of devices, including, but not limited to: analogue microphones, digital microphones, accelerometers or ultrasonic transducers. The invention may also be used in a number of applications, including, but not limited to, consumer applications, medical applications, industrial applications and automotive applications. For example, typical consumer applications include portable audio players, laptops, mobile phones, PDAs and personal computers. Typical medical applications include hearing aids. Typical industrial applications include active noise cancellation. Typical automotive applications include hands-free sets, acoustic crash sensors and active noise cancellation.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

What is claimed is:

1. An integrated circuit having a signal path, the integrated circuit comprising:
means for coupling a test signal to a node of the signal path via a parasitic capacitance of the integrated circuit associated with the node.

2. An integrated circuit as claimed in claim 1, further comprising a conductive region associated with the parasitic capacitance, wherein the means for coupling the test signal is configured to couple the test signal to the parasitic capacitance using the conductive region.

3. An integrated circuit as claimed in claim 1, wherein the conductive region is a shielding element associated with the signal path.

4. An integrated circuit as claimed in claim 1, wherein the conductive region is a region of n-type or p-type semiconductor material.

5. An integrated circuit as claimed in claim 1, further comprising switching means for selectively coupling the test signal to the node via the parasitic capacitance.

6. An integrated circuit as claimed in claim 5, wherein the switching means is configured to selectively couple a reference voltage to the parasitic capacitance during a non-test mode of operation.

7. An integrated circuit as claimed in claim 6, wherein the reference voltage is a ground reference voltage.

8. An integrated circuit as claimed in claim 1, further comprising a signal source for generating the test signal.

9. An integrated circuit as claimed in claim 8, wherein the signal source is adapted to provide a test signal having a variable frequency and/or amplitude.

10. An integrated circuit as claimed in claim 1, wherein the node comprises a bond pad.

11. An integrated circuit as claimed in claim 1, wherein the node is an input terminal of an amplifier suitable for connection to a capacitive transducer.

12. An integrated circuit as claimed in claim 1 wherein the integrated circuit is configured to process a signal associated with a capacitive transducer.

13. A method of applying a test signal to a node of a signal path of an integrated circuit, the method comprising the steps of:
coupling a test signal to the node via a parasitic capacitance of the integrated circuit associated with the node.

14. A method as claimed in claim 13, wherein the step of coupling the test signal comprises the step of coupling the test signal via a conductive region associated with the parasitic capacitance.

15. A method as claimed in claim 13, wherein the conductive region is a shielding element associated with the signal path.

16. A method as claimed in claim 13, wherein the conductive region is a region of n-type or p-type semiconductor material.

17. A method as claimed in claim 13, further comprising the step of providing switching means, and operating the switching means to selectively couple the test signal to the node via the parasitic capacitance.

18. A method as claimed in claim 17, further comprising the step of selectively coupling a reference voltage to the parasitic capacitance during a non-test mode of operation.

19. A method as claimed in claim 18, wherein the reference voltage is a ground reference voltage.

20. A method as claimed in claim 13, further comprising the steps of varying the frequency and/or amplitude of the test signal during a test mode of operation.

21. A method as claimed in claim 13, wherein the method is performed on a parasitic capacitance associated with a bond pad.

22. A method as claimed in claim 13, wherein the method is performed on a node of an input terminal of an amplifier suitable for connection to a capacitive transducer.

23. A method of testing an assembly comprising a first integrated circuit (100) comprising a capacitive transducer and a second integrated circuit (102) comprising associated electronic circuitry, the method comprising the steps of:
mounting the first integrated circuit and the second integrated circuit on a common substrate; and
testing the first integrated circuit and/or the second integrated circuit using the method as defined in claim 13 prior to the step of electrically connecting the first integrated circuit and the second integrated circuit.

24. A method of testing an assembly comprising a first integrated circuit (100) comprising a capacitive transducer and a second integrated circuit (102) comprising associated electronic circuitry, the method comprising the steps of:
mounting the first integrated circuit and the second integrated circuit on a common substrate;
electrically connecting the first integrated circuit and the second integrated circuit; and
testing the first integrated circuit and/or the second integrated circuit using the method as defined in claim 13.

25. A method as claimed in claim 24, wherein the method comprises the step of testing the continuity of one or more interconnection points between the first integrated circuit and the second integrated circuit.

26. A method as claimed in claim 24, wherein the method comprises the step of testing the function of the capacitive transducer on the first integrated circuit (100).

27. A method as claimed in claim 24, wherein the method comprises the step of testing the function of an amplifier provided on the second integrated circuit.

28. A method as claimed in claim 23, further comprising the steps of:
packaging the first integrated circuit and the second integrated circuit; and
testing the first integrated circuit and/or the second integrated circuit using the method as defined in claim 13.

29. A device as claimed in claim 12 wherein the device is at least one of; a MEMS devices; an ultrasound imager; a sonar transmitter; a sonar receiver; a mobile phone; a personal desktop assistant; an MP3 player; and a laptop.
